(19) United States
(12) Patent Application Publication
(10) Pub. No.: US 2025/0149427 A1
(43) Pub. Date: May 8, 2025

(54) EMBEDDED PASSIVE DEVICES FOR INTEGRATED CIRCUITS AND METHODS OF FORMING THE SAME

(71) Applicant: Taiwan Semiconductor Manufacturing Co., Ltd., Hsinchu (TW)

(72) Inventors: Chia-Yueh Chou, Taoyuan City (TW); Hsiang-Ku Shen, Hsinchu (TW); Chen-Chiu Huang, Taichung City (TW); Yu-Bey Wu, Hsinchu (TW); Dian-Hau Chen, Hsinchu (TW)

(21) Appl. No.: 18/434,222

(22) Filed: Feb. 6, 2024

Related U.S. Application Data
(60) Provisional application No. 63/595,590, filed on Nov. 2, 2023.

(51) Int. Cl. H01L 23/498; H01L 23/00; H01L 25/065

(52) U.S. Cl. CPC H01L 23/49838; H01L 23/49827; H01L 24/03; H01L 24/08; H10D 1/68; H01L 25/0657; H01L 2224/0391; H01L 2224/08146; H01L 2224/08147; H01L 2225/06503; H01L 2924/1205

(57) ABSTRACT

In an embodiment, a device includes: a plurality of redistribution lines over a semiconductor substrate, the redistribution lines including trace portions extending along the semiconductor substrate; a first passivation layer over the redistribution lines, the first passivation layer filling an entirety of an area between the trace portions of the redistribution lines; a passive device over the first passivation layer; a dielectric layer over the passive device; and a die connector extending through the dielectric layer, the die connector physically and electrically coupled to the passive device.

### PRIORITY CLAIM AND CROSS-REFERENCE

This application claims the benefit of U.S. Provisional Application No. 63/595,590, filed on Nov. 2, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller semiconductor dies with more components has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 are cross-sectional views of intermediate stages in the manufacturing of an integrated circuit die, in accordance with some embodiments.

FIGS. 14A-14D are detailed views of embedded passive devices, in accordance with some embodiments.

FIG. 15 is a cross-sectional view of a die structure, in accordance with some embodiments.

FIG. 16 is a cross-sectional view of a die structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a passivation layer is formed over redistribution lines of an integrated circuit die. The passivation layer may be formed to be thick and flat. For example, the passivation layer may be formed to initially cover the redistribution lines and then may be planarized, after which the passivation layer still extends over and between the redistribution lines. The entirety of each respective area between respective redistribution lines may be filled by the passivation layer. Thus, there may be a large space on which embedded passive devices may be formed in subsequent processing. In this way, more passive devices may be embedded in an integrated circuit die, allowing for a greater degree of device integration.

FIGS. 1-13 are cross-sectional views of intermediate stages in the manufacturing of an integrated circuit die 100 (see FIG. 13), in accordance with some embodiments. The integrated circuit die 100 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or combinations thereof (e.g., a system-on-a-chip (SoC) die). The integrated circuit die 100 may be formed in a wafer, which may include different device regions that are singulated in subsequent steps to form a plurality of integrated circuit dies.

In FIG. 1, a semiconductor substrate 102 is formed or provided. The semiconductor substrate 102 may be a silicon substrate, doped or undoped, or an active layer of a semiconductor-on-insulator (SOI) substrate. The semiconductor substrate 102 may include other semiconductor materials, such as germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 102 has an active surface (e.g., the surface facing upwards in FIG. 1), sometimes called a front side, and an inactive surface (e.g., the surface facing downwards in FIG. 1), sometimes called a back side. Devices are formed at the active surface of the semiconductor substrate 102. The devices may be active devices (e.g., transistors, diodes, etc.) or passive devices (e.g., capacitors, inductors, resistors, etc.). The inactive surface may be free of devices. The device may be formed in a suitable front-end of line (FEOL) process.

An interconnect structure 104 is formed over the active surface of the semiconductor substrate 102. The interconnect structure 104 interconnects the devices of the semiconductor substrate 102 to form an integrated circuit. The interconnect structure 104 may be formed in a suitable back-end of line (BEOL) process. The interconnect structure 104 may include one or more dielectric layer(s) and respective metallization pattern(s) in the dielectric layer(s). Acceptable dielectric materials for the dielectric layers include oxides such as silicon oxide, aluminum oxide, or the like; nitrides such as silicon nitride, silicon oxynitride; combinations thereof; or the like. The dielectric layer(s) may be formed of a low-k (LK) dielectric material such as carbon-doped silicon oxide, an extremely low-k (ELK) dielectric material such as porous carbon-doped silicon oxide, or the like. Other acceptable dielectric materials may be utilized. The metallization patterns may include conductive vias and/or conductive lines to interconnect the devices of the semiconductor substrate 102. The metallization patterns may be formed of a conductive material, such as a metal, such as copper, cobalt, aluminum, gold, combinations thereof, or the like. The metallization patterns may be formed by a damascene process, such as a single damascene process, a dual damascene process, or the like.

Contact pads 106 are formed at the front side of the integrated circuit die 100. The contact pads 106 may be pads, conductive pillars, or the like, to which external connections are made. The contact pads 106 may be in and/or on the interconnect structure 104. For example, the contact pads 106 may be part of an upper metallization pattern of the interconnect structure 104. The contact pads 106 can be formed of a metal, such as copper, aluminum, a copper alloy, combinations thereof, or the like, which can be formed by, for example, plating, or the like.

A dielectric layer 108 is at the front side of the integrated circuit die 100. The dielectric layer 108 may be in and/or on the interconnect structure 104. For example, the dielectric layer 108 may be an upper dielectric layer of the interconnect structure 104. The dielectric layer 108 laterally surrounds the contact pads 106. The dielectric layer 108 may be an oxide, a nitride, a polymer, the like, or a combination thereof. The dielectric layer 108 may be formed, for example, by spin coating, lamination, chemical vapor deposition (CVD), or the like.

In some embodiments (not separately illustrated), the integrated circuit die 100 is a stacked device that includes multiple semiconductor substrates 102. For example, the integrated circuit die 100 may be a memory device that includes multiple memory dies, such as a hybrid memory cube (HMC) module, a high bandwidth memory (HBM) module, or the like. In such embodiments, the integrated circuit die 100 includes multiple semiconductor substrates 102 interconnected by through-substrate vias (TSVs), such as through-silicon vias. Each of the semiconductor substrates 102 may (or may not) have an interconnect structure 104.

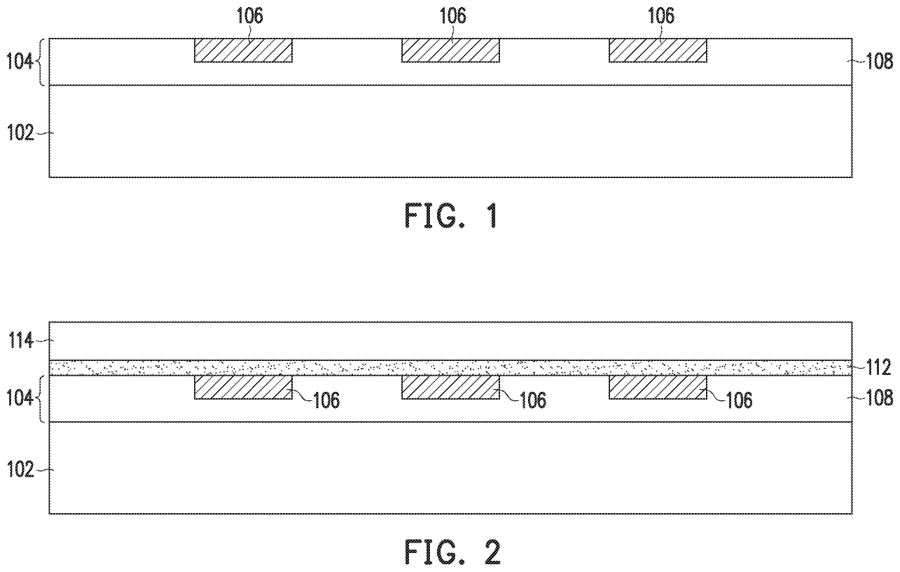

In FIG. 2, a passivation layer 114 is formed over the interconnect structure 104 (e.g., over the dielectric layer 108 and the contact pads 106). The passivation layer 114 may be formed of one or more acceptable dielectric materials, such as silicon nitride, silicon oxide, combinations thereof, or the like. Other acceptable dielectric materials include polymers such as polyimide, solder resist, polybenzoxazole (PBO), a benzocyclobutene (BCB) based polymer, molding compound, or the like. The passivation layer 114 may be formed by deposition (e.g., CVD), spin coating, lamination, combinations thereof, or the like. The passivation layer 114 may be formed to a large thickness, such as a thickness in the range of 2 kÅ to 10 kÅ. Additionally, the passivation layer 114 may be planarized, such as by a chemical mechanical polish (CMP).

An etch stop layer 112 is formed between the passivation layer 114 and the interconnect structure 104. The etch stop layer 112 may be formed of a dielectric material having a high etching selectivity from the etching of the passivation layer 114, such as silicon nitride, silicon oxynitride, or the like, which may be formed by any suitable deposition process, such as CVD, atomic layer deposition (ALD), or the like.

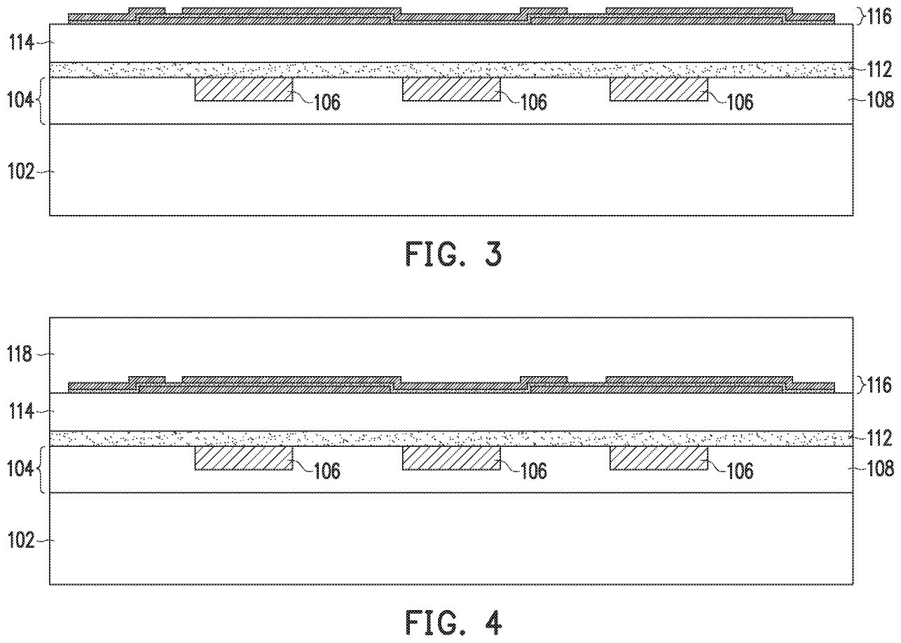

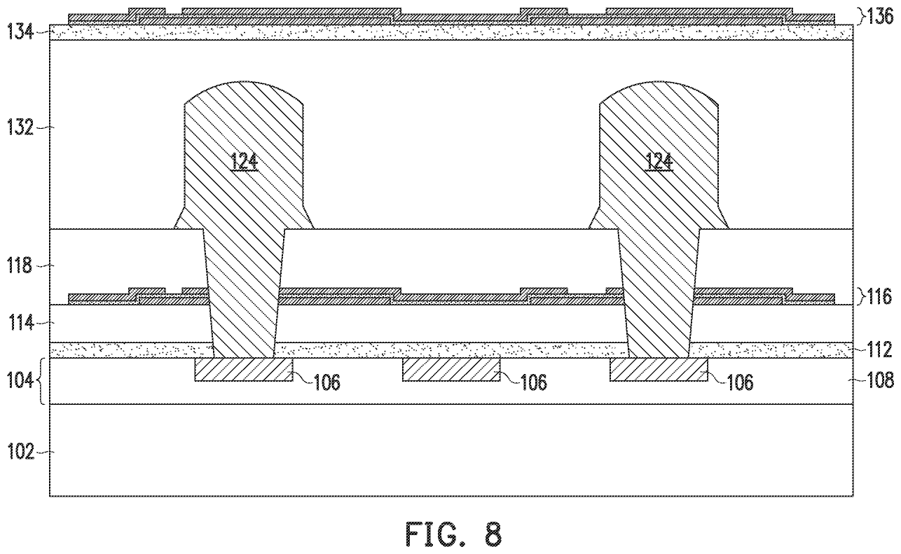

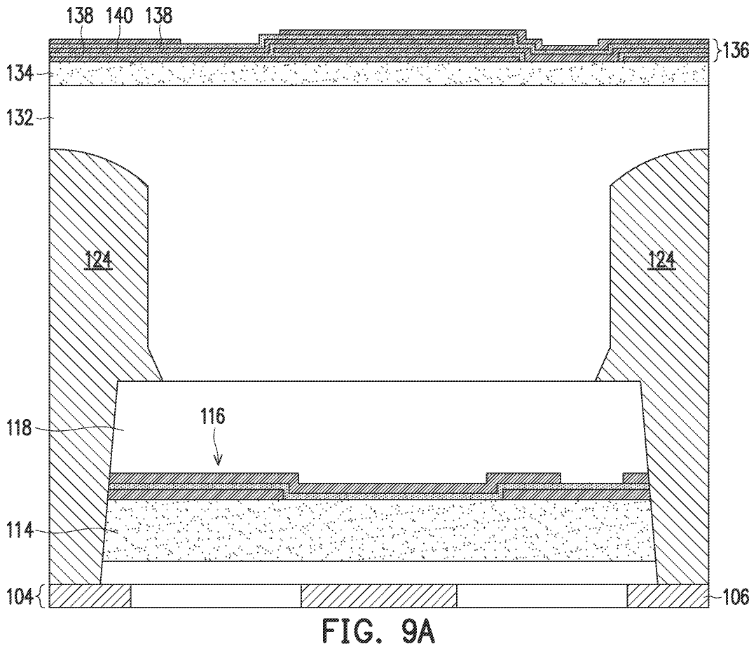

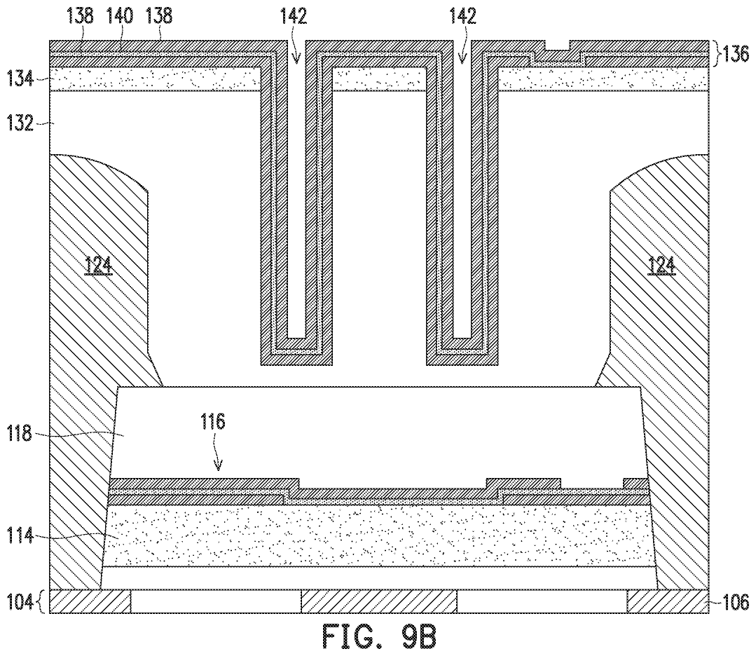

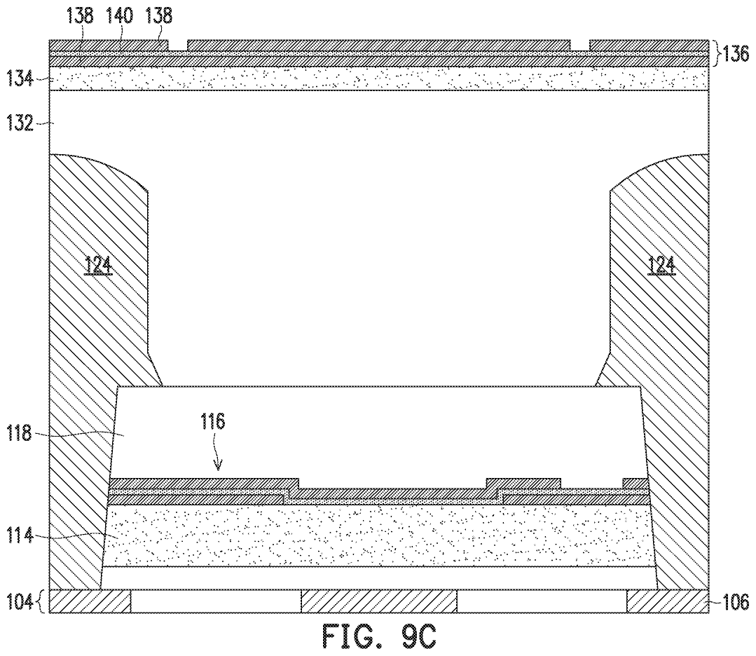

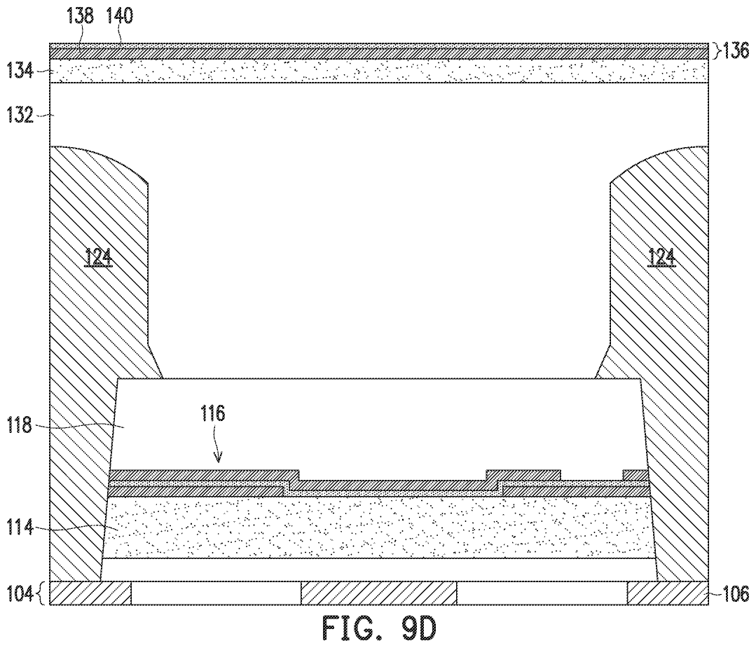

In FIG. 3, passive devices 116 are optionally formed on the passivation layer 114. The passive devices 116 may include capacitors, inductors, resistors, and the like. The passive devices 116 are embedded passive devices, and may be electrically coupled to the devices of the semiconductor substrate 102. Details regarding the structure and formation of passive devices will be subsequently described for FIGS. 8 and 9A-9D.

In FIG. 4, a passivation layer 118 is formed over the passive devices 116 (if present) and the passivation layer 114. The passivation layer 118 may be formed of one or more acceptable dielectric materials, such as silicon nitride, silicon oxide, combinations thereof, or the like. Other acceptable dielectric materials include polymers such as polyimide, solder resist, polybenzoxazole (PBO), a benzocyclobutene (BCB) based polymer, molding compound, or the like. The passivation layer 118 may be formed by deposition (e.g., CVD), spin coating, lamination, combinations thereof, or the like. The passivation layer 118 may be formed to a large thickness, such as a thickness in the range of 2 kÅ to 10 kÅ. Additionally, the passivation layer 118 may be planarized, such as by a chemical mechanical polish (CMP).

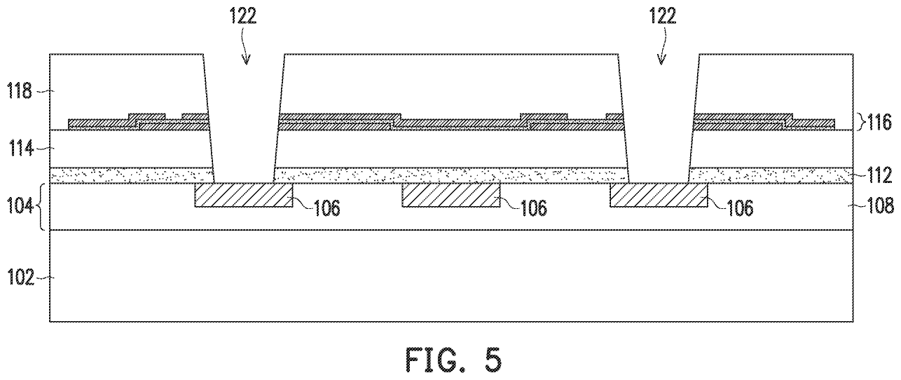

In FIG. 5, openings 122 are patterned through the passivation layer 118, the passivation layer 114, and the etch stop layer 112, thereby exposing the contact pads 106. The openings 122 may be formed using acceptable photolithography and etching techniques. For example, the openings 122 may be formed through the various layers by one or more etching process(es) that have appropriate etch selectivity. When the passive devices 116 are formed, the openings 122 can be patterned around the passive devices 116, such that the openings 122 are disposed between adjacent passive devices 116.

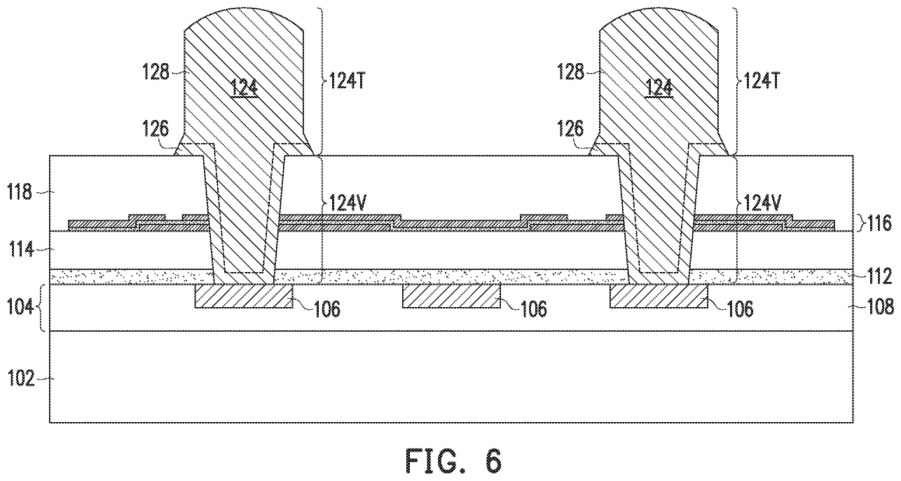

In FIG. 6, redistribution lines 124 are formed. The redistribution lines 124 have trace portions 124T on and extending along the top surface of the passivation layer 118. For example, the trace portions 124T are conductive lines that extend lengthwise parallel to a major surface of the semiconductor substrate 102. Thus, the redistribution lines 124 extend along the semiconductor substrate 102 in respective lengthwise directions. A trace portion 124T of a redistribution line 124 has a length (in its lengthwise direction) and a width (in a direction perpendicular to the lengthwise direction), where the length is greater than the width. The redistribution lines 124 may also have one or more via portions 124V in respective ones of the openings 122 (through the passivation layer 118, the passivation layer 114, and the etch stop layer 112) that are physically and electrically coupled to the contact pads 106. The redistribution lines 124 may physically contact the contact pads 106. Some of the via portions 124V may be used to electrically couple the passive devices 116 to the devices of the semiconductor substrate 102.

As an example to form the redistribution lines 124, a seed layer 126 may be formed on the top surface of the passivation layer 118 and in the openings 122 (e.g., on the exposed portions of the contact pads 106). In some embodiments, the seed layer 126 is a metal layer, which may be a single layer or a composite layer including a plurality of sub-layers formed of different materials. In some embodiments, the seed layer 126 includes a titanium layer and a copper layer over the titanium layer. The seed layer 126 may be formed using, for example, physical vapor deposition (PVD) or the like. Optionally, a liner (not separately illustrated), such as a diffusion barrier layer, an adhesion layer, or the like may be formed in the openings 122 before the seed layer 126. The liner may include titanium, titanium nitride, tantalum, tantalum nitride, or the like. A photoresist (not separately illustrated) is then formed and patterned on the seed layer 126. The photoresist may be formed by spin coating or the like and may be exposed to light for patterning. The pattern of the photoresist corresponds to the redistribution lines 124. The patterning forms openings through the photoresist to expose the seed layer 126. A conductive material 128 is then formed in the openings of the photoresist and on the exposed portions of the seed layer 126. The conductive material 128 may be formed by plating, such as by electroplating, electroless plating, or the like. The conductive material 128 may include a metal, such as copper, silver, cobalt, titanium, tungsten, aluminum, combinations thereof, or the like. For example, the conductive material 128 may be copper, a copper-silver alloy, or a copper-cobalt alloy, plated using the seed layer 126. Then, the photoresist and portions of the seed layer 126 on which the conductive material 128 are not formed are removed. The photoresist may be removed by an acceptable ashing or stripping process, such as using an oxygen plasma or the like. Once the photoresist is removed, exposed portions of the seed layer 126 are removed, such as by using an acceptable etching process. An anneal process may optionally be performed. The remaining portions of the seed layer 126 and conductive material 128 form the redistribution lines 124.

The redistribution lines 124 may have any type of top surfaces, given the application of the integrated circuit die to be formed. In the illustrated embodiment, the redistribution lines 124 have convex top surfaces. In another embodiment, the redistribution lines 124 can have flat top surfaces, concave top surfaces, polygonal top surfaces, or the like. Additionally, the trace portions 124T may have any type of sidewalls, given the application of the integrated circuit die 100 to be formed. In the illustrated embodiment, the trace portions 124T have sidewalls that are spaced apart by a tapering width that decreases in a direction extending away from the semiconductor substrate 102. In another embodiment, the trace portions 124T have substantially vertical sidewalls that are spaced apart by a constant width.

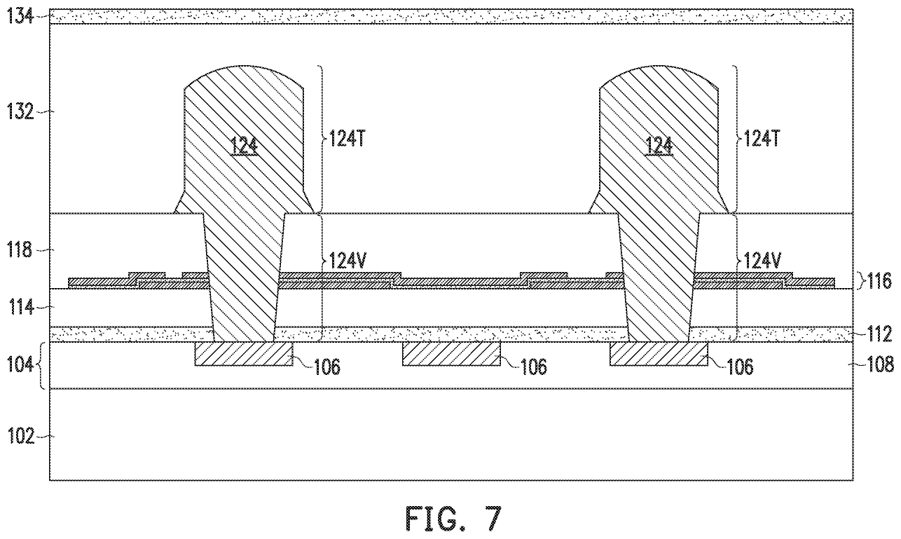

In FIG. 7, a passivation layer 132 is formed on the redistribution lines 124 and the passivation layer 118. The passivation layer 132 may be formed of one or more acceptable dielectric materials, such as silicon nitride, silicon oxide, combinations thereof, or the like. Other acceptable dielectric materials include polymers such as polyimide, solder resist, polybenzoxazole (PBO), a benzocyclobutene (BCB) based polymer, molding compound, or the like. The passivation layer 132 may be formed by deposition (e.g., CVD), spin coating, lamination, combinations thereof, or the like.

The passivation layer 132 may be formed to a large initial thickness, such as a thickness in the range of 1.5 kÅ to 100 kÅ. The initial thickness of the passivation layer 132 is large enough to cover the trace portions 124T of the redistribution lines 124. The redistribution lines 124 may have a large height, such as a height in the range of 1.5 kÅ to 100 kÅ, which may cause the top surface of the passivation layer 132 to initially have a low degree of planarity. To compensate for this, the passivation layer 132 may be planarized, such as by a chemical mechanical polish (CMP), after the passivation layer 132 is deposited. As a result of planarization, the top surface of the passivation layer 132 may have a high degree of planarity, such as a degree of planarity in the range of 0 kÅ to 50 kÅ. The top surface of the passivation layer 132 may have a higher degree of planarity than the top surface of the passivation layer 118. The thickness of the passivation layer 132 may be decreased during planarization. However, the initial thickness of the passivation layer 132 is large enough that, even when the thickness of the passivation layer 132 is decreased, the passivation layer 132 still covers the redistribution lines 124. In some embodiments, after planarization, the portions of the passivation layer 132 remaining over the redistribution lines 124 have a thickness in the range of 2 kÅ to 10 kÅ. Thus, the passivation layer 132 may be thick and flat (over and between the redistribution lines 124), which may provide a large space on which passive devices may be formed in subsequent processing. The planar top surface of the passivation layer 132 extends continuously over the redistribution lines 124 and the areas between the redistribution lines 124. The entirety of each respective area between the trace portions 124T of the redistribution lines 124 may be filled by the passivation layer 132. The redistribution lines 124 are spaced apart from the subsequently formed passive devices by the portions of the passivation layer 132 over the redistribution lines 124.

An etch stop layer 134 is formed on the passivation layer 132. The etch stop layer 134 will be located between the passivation layer 132 and a subsequently formed overlying passivation layer. The etch stop layer 134 may be formed of a dielectric material having a high etching selectivity from the etching of the overlying passivation layer, such as silicon nitride, silicon oxynitride, or the like, which may be formed by any suitable deposition process, such as CVD, ALD, or the like.

In FIG. 8, passive devices 136 are optionally formed on the etch stop layer 134. The passive devices 136 may physically contact a top surface of the etch stop layer 134. The passive devices 136 may include capacitors, inductors, resistors, and the like. The passive devices 136 are embedded passive devices, and may be electrically coupled to the devices of the semiconductor substrate 102. As subsequently described in greater detail, a passive device 136 may include one or more metal layer(s) and one or more insulating layer(s). FIGS. 9A-9D are detailed views of example passive devices 136 that may be formed. The integrated circuit die 100 may include any desired combination and quantity of the illustrated passive devices 136.

In some embodiments, the passive devices 136 include plate capacitors, as shown by FIG. 9A. The plate capacitors may have a metal-insulator-metal (MIM) structure, including a three-dimensional corrugated stack of metal layers 138 separated by insulating layers 140. The metal layers 138 may include horizontal metal plates, where a plate capacitor includes at least two metal plates and a portion of an insulating layer 140 between the metal plates. For example, a plate capacitor may include a lower metal plate, an insulating layer on the lower metal plate, and an upper metal plate on the insulating layer. A plate capacitor may be a bi-plate capacitor that includes two metal plates, or may be a multi-plate capacitor that includes more than two metal plates.

As an example to form the plate capacitors, a patterned metal layer 138 may be formed. The metal layer 138 may be formed of copper, cobalt, aluminum, gold, combinations thereof, or the like, and can be formed by, for example, plating, or the like. The metal layer 138 may be patterned after it is initially formed (e.g., using acceptable photolithography and etching techniques) or may be selectively formed in a desired pattern (e.g., using acceptable masking and plating techniques). The pattern of the metal layer 138 defines metal plates. An insulating layer 140 may be then formed on the patterned metal layer 138 and in any openings through the patterned metal layer 138. The insulating layer 140 may be formed of a dielectric material such as silicon oxide, silicon oxynitride, silicon oxycarbide, or the like, which may be formed by any suitable deposition process, such as CVD, ALD, or the like. Another patterned metal layer 138 may then be formed on the insulating layer 140. Specifically, any desired quantity of patterned metal layers 138 and insulating layers 140 may be formed by repeating the previously described process.

In some embodiments, the passive devices 136 include deep-trench capacitors, as shown by FIG. 9B. The deep-trench capacitors may include a three-dimensional corrugated stack of metal layers 138 separated by insulating layers 140. The metal layers 138 may include metal vias, where a deep-trench capacitor includes at least two metal vias (one located within the other) and a portion of an insulating layer 140 between the vias. For example, a deep-trench capacitor may include an outer metal via, an insulating layer on the outer metal via, and an inner metal via on the insulating layer. The metal vias may extend beneath the top surfaces of the redistribution lines 124. A deep-trench capacitor may be a single-trench capacitor that includes the metal vias in a single recess 142, or may be a multi-trench capacitor that includes the metal vias in multiple recesses 142.

As an example to form the deep-trench capacitors, recesses 142 may be patterned through the etch stop layer 134 and in the passivation layer 132, such as by using acceptable photolithography and etching techniques. The recesses 142 may extend into, but not through, the passivation layer 132, and may extend beneath the top surfaces of the redistribution lines 124. Once the recesses 142 have been patterned, a patterned metal layer 138 may be formed in the recesses 142. The metal layer 138 may be formed of copper, cobalt, aluminum, gold, combinations thereof, or the like, and can be formed by, for example, plating, or the like. The metal layer 138 may be patterned after it is initially formed (e.g., using acceptable photolithography and etching techniques) or may be selectively formed in a desired pattern (e.g., using acceptable masking and plating techniques). The pattern of the metal layer 138 defines metal vias. An insulating layer 140 may be then formed on the patterned metal layer 138, in any openings through the patterned metal layer 138, and in the recesses 142. The insulating layer 140 may be formed of a dielectric material such as silicon oxide, silicon oxynitride, silicon oxycarbide, or the like, which may be formed by any suitable deposition process, such as CVD, ALD, or the like. Another patterned metal layer 138 may then be formed on the insulating layer 140 and in the recesses 142. Specifically, any desired quantity of patterned metal layers 138 and insulating layers 140 may be formed by repeating the previously described process.

In some embodiments, the passive devices 136 include resistors, as shown by FIG. 9C. The resistors may include a three-dimensional flat stack of metal layers 138 separated by insulating layers 140. Specifically, the metal layers 138 may include a lower metal layer 138 and a patterned upper metal layer 138. The patterned upper metal layer 138 may include metal wires that act as resistive elements. For example, a resistor may include a metal plane, an insulating layer on the metal plane, and a metal wire on the insulating layer.

As an example to form the resistors, a lower metal layer 138 may be formed in the recesses 142. The lower metal layer 138 may be formed of copper, cobalt, aluminum, gold, combinations thereof, or the like, and can be formed by, for example, plating, or the like. The lower metal layer 138 may be a metal plane that is unpatterned. An insulating layer 140 may be then formed on the lower metal layer 138. The insulating layer 140 may be formed of a dielectric material such as silicon oxide, silicon oxynitride, silicon oxycarbide, or the like, which may be formed by any suitable deposition process, such as CVD, ALD, or the like. A patterned upper metal layer 138 may then be formed on the insulating layer 140. The upper metal layer 138 may be formed of copper, cobalt, aluminum, gold, combinations thereof, or the like, and can be formed by, for example, plating, or the like. The upper metal layer 138 may be patterned after it is initially formed (e.g., using acceptable photolithography and etching techniques) or may be selectively formed in a desired pattern (e.g., using acceptable masking and plating techniques). The pattern of the metal layer 138 defines metal wires which act as resistive elements. Each metal wire has a width and a length that are selected based on the desired resistivity of the resistor.

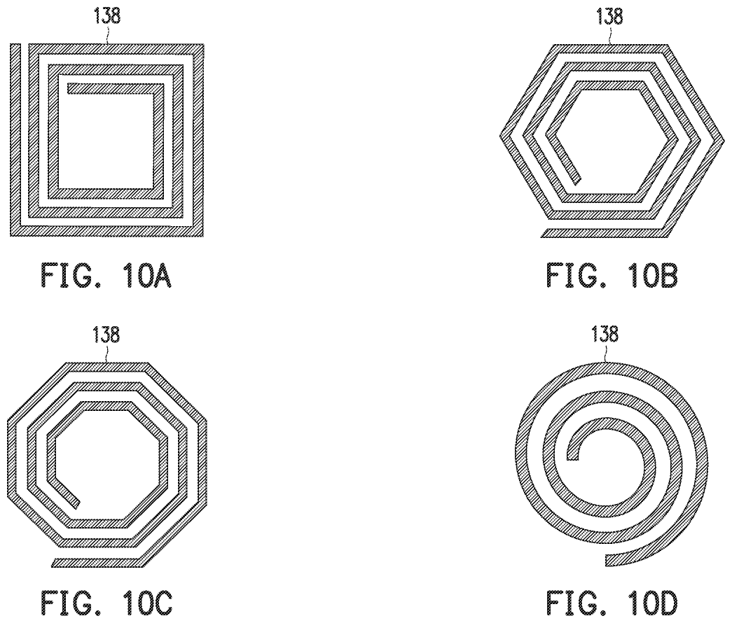

In some embodiments, the passive devices 136 include inductors, as shown by FIG. 9D. The inductors may include a patterned metal layer 138 and an overlying insulating layer 140. The patterned metal layer 138 may include metal coils which act as inductive elements. For example, an inductor may include a metal coil and an insulating layer on the metal coil. Each metal coil is wound based on the desired inductance of the inductor. A metal coil is a loop or spiral that emanates from a first end and terminates at a second end. The metal coils may have any desired shape, in a top-down view. FIGS. 10A-10D are top-down views of metal coils. A metal coil may be a square coil (as shown in FIG. 10A), a hexagonal coil (as shown in FIG. 10B), an octagonal coil (as shown in FIG. 10C), a round coil (as shown in FIG. 10D), or the like.

As an example to form the inductors, a patterned metal layer 138 may be formed. The metal layer 138 may be formed of copper, cobalt, aluminum, gold, combinations thereof, or the like, and can be formed by, for example, plating, or the like. The metal layer 138 may be patterned after it is initially formed (e.g., using acceptable photolithography and etching techniques) or may be selectively formed in a desired pattern (e.g., using acceptable masking and plating techniques). The pattern of the metal layer 138 defines metal coils which act as inductive elements. An insulating layer 140 may be then formed on the patterned metal layer 138 and in any openings through the patterned metal layer 138. The insulating layer 140 may be formed of a dielectric material such as silicon oxide, silicon oxynitride, silicon oxycarbide, or the like, which may be formed by any suitable deposition process, such as CVD, ALD, or the like.

Additional features may be formed on the etch stop layer 134. For example, dummy metal films may be formed in addition to the passive devices 136. A dummy metal film may have a similar structure as the passive devices 136 (including, e.g., one or more metal layer(s)), and may be formed in a same process as the passive devices 136. Dummy metal films may be formed as desired to tune warpage of the integrated circuit die 100.

In FIG. 11, a dielectric layer 152 is formed on the passive devices 136 and the etch stop layer 134. The dielectric layer 152 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a combination thereof; or the like. The dielectric layer 152 may be formed, for example, by CVD, ALD, or the like. For example, the dielectric layer 152 may be formed of silicon oxide deposited using TEOS. The dielectric material of the dielectric layer 152 may be different than the dielectric material of the passivation layer 132. For example, the dielectric layer 152 may be formed of silicon oxide while the passivation layer 132 may be formed of silicon nitride. Similar to the passivation layer 132, the dielectric layer 152 may be thick and flat, which may provide a large space on which passive devices may be formed in subsequent processing.

An etch stop layer 154 may be formed on the dielectric layer 152. The etch stop layer 154 will be located between the dielectric layer 152 and a subsequently formed overlying dielectric layer. The etch stop layer 154 may be formed of a dielectric material having a high etching selectivity from the etching of the overlying passivation layer, such as silicon nitride, silicon oxynitride, or the like, which may be formed by any suitable deposition process, such as CVD, ALD, or the like.

Passive devices 156 are optionally formed on the etch stop layer 154. The passive devices 156 may include capacitors, inductors, resistors, and the like. The passive devices 156 are embedded passive devices, and may be electrically coupled to the devices of the semiconductor substrate 102. The passive devices 156 may be any of those previously described for FIGS. 9A-9D. The integrated circuit die 100 may include any desired combination and quantity of the passive devices 156. As previously described in greater detail, a passive device 156 may include one or more metal layer(s) and insulating layer(s).

A dielectric layer 158 may be formed on the passive devices 156 and the etch stop layer 154. The dielectric layer 158 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a combination thereof; or the like. The dielectric layer 158 may be formed, for example, by CVD, ALD, or the like. For example, the dielectric layer 158 may be formed of silicon oxide deposited using TEOS.

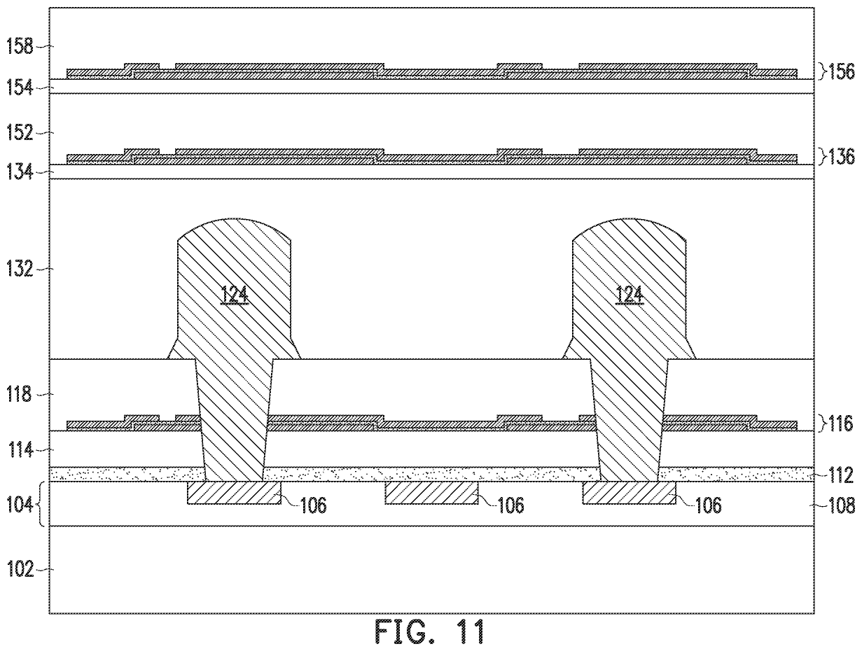

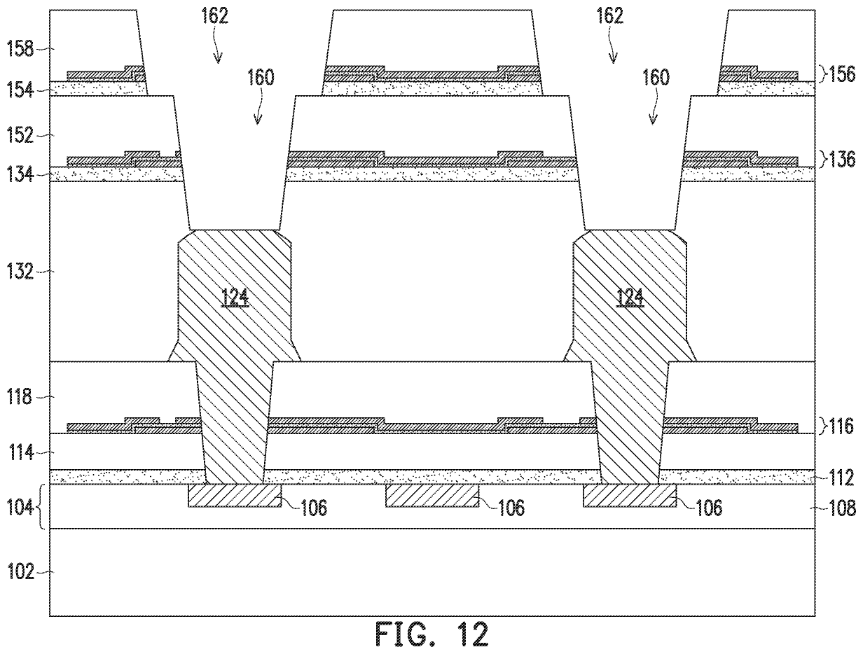

In FIG. 12, die connector openings (including via openings 160 and bond pad openings 162) are patterned in the dielectric layer 158, the etch stop layer 154, the dielectric layer 152, the etch stop layer 134, and the passivation layer 132, thereby exposing the redistribution lines 124. The die connector openings may be formed by acceptable photolithography and etching techniques. When the passive devices 156 are formed, the bond pad openings 162 can be patterned around the passive devices 156, such that the bond pad openings 162 are disposed between adjacent passive devices 156. Similarly, the via openings 160 can be patterned around the passive devices 136, such that the via openings 160 are disposed between adjacent passive devices 136.

The die connector openings may be formed by a damascene process. In this embodiment, the die connector openings are formed by a single damascene process. In a single damascene process, the bond pad openings 162 are formed through the dielectric layer 158 and the etch stop layer 154, while the via openings 160 are formed through the dielectric layer 152, the etch stop layer 134, and the passivation layer 132. The via openings 160 expose the redistribution lines 124. In another embodiment, the etch stop layer 154 and the dielectric layer 158 are omitted, and the die connector openings are formed by a dual damascene process. In a dual damascene process, the bond pad openings 162 are formed through an upper portion of the dielectric layer 152, while the via openings 160 are formed through a lower portion of the dielectric layer 152, the etch stop layer 134, and the passivation layer 132.

In FIG. 13, die connectors 164 (including vias 166 and bond pads 168) are formed in the die connector openings (including, respectively, the via openings 160 and the bond pad openings 162). The die connectors 164 may be formed of a suitable conductive material, such as copper, tungsten, aluminum, silver, gold, a combination thereof, or the like, which can be formed by, for example, plating or the like. The excess portions of the conductive material, which excess portions are over the top surface of the dielectric layer 158, are then removed. In some embodiments, a planarization process such as a chemical mechanical polish (CMP), an etch-back process, combinations thereof, or the like may be utilized. After the planarization process, the top surfaces of the die connectors 164 may be coplanar (within process variations) with the top surface of the dielectric layer 158. The die connectors 164 are physically and electrically coupled to the redistribution lines 124. The die connectors 164 may physically contact the trace portions 124T of the redistribution lines 124. Some of the die connectors 164 (e.g., the vias 166) may be used to electrically couple the passive devices 136, 156 to the devices of the semiconductor substrate 102.

The bond pads 168 of the die connectors 164 are disposed in the dielectric layer 158, while the vias 166 of the die connectors 164 are disposed in the dielectric layer 152 and the passivation layer 132. The vias 166 extend through the portions of the passivation layer 132 that are over the redistribution lines 124.

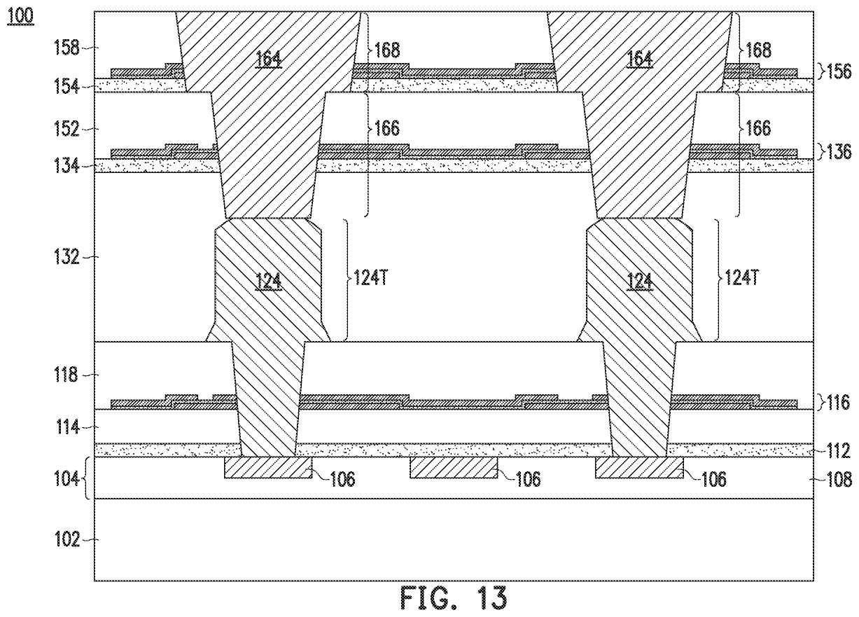

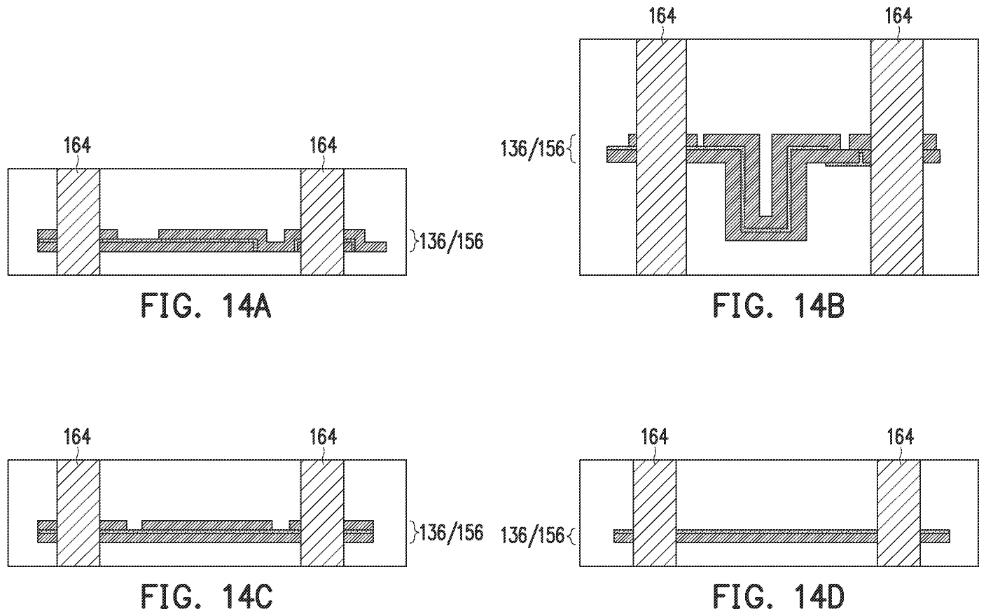

FIGS. 14A-14D are detailed views of embedded passive devices, in accordance with some embodiments. The passive devices may be the passive devices 136 or the passive devices 156 (previously described). A passive device may be a plate capacitor (as shown in FIG. 14A), a deep-trench capacitor (as shown in FIG. 14B), a resistor (as shown in FIG. 14C), or an inductor (as shown in FIG. 14D). The passive devices may be disposed around and/or coupled to die connectors 164. The die connectors 164 may be physically and electrically coupled to input/output terminals of the passive devices, as well as to the underlying redistribution lines 124 (see FIG. 13).

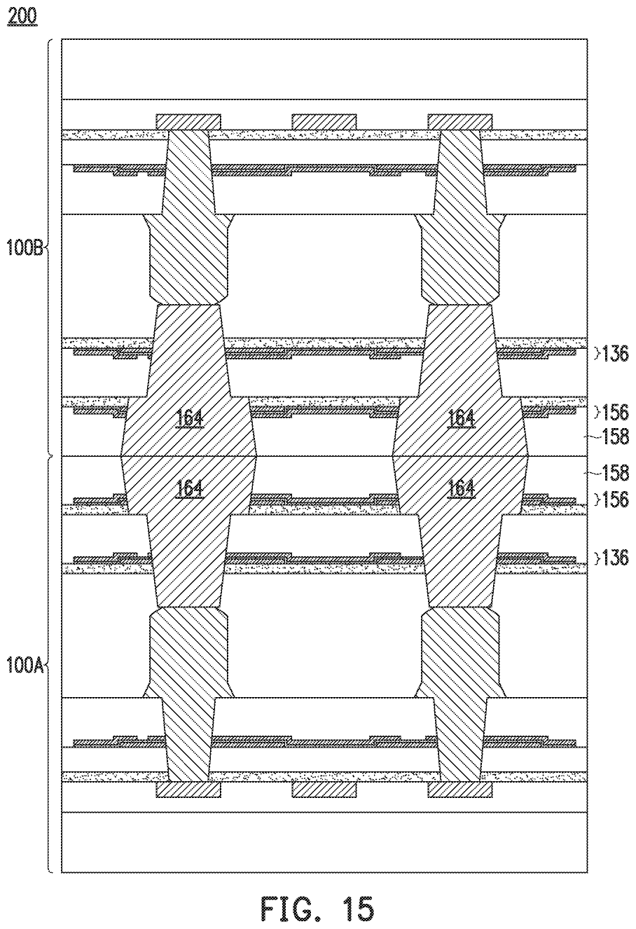

FIG. 15 is a cross-sectional view of a die structure 200, in accordance with some embodiments. The die structure 200 is a stack of integrated circuit dies 100 (including a first integrated circuit die 100A and a second integrated circuit die 100B). The die structure 200 is formed by bonding the integrated circuit dies 100 together. Some of the passive devices 136, 156 of the first integrated circuit die 100A may be coupled to some of the passive devices 136, 156 of the second integrated circuit die 100B by the bonds.

As an example of the bonding process, the second integrated circuit die 100B may be bonded to the first integrated circuit die 100A by hybrid bonding. The dielectric layer 158 of the second integrated circuit die 100B is directly bonded to the dielectric layer 158 of the first integrated circuit die 100A through dielectric-to-dielectric bonding, without using any adhesive material (e.g., die attach film). The die connectors 164 of the second integrated circuit die 100B of the second integrated circuit die 100B are directly bonded to the die connectors 164 of the first integrated circuit die 100A through metal-to-metal bonding, without using any eutectic material (e.g., solder). The bonding may include a pre-bonding and an annealing. During the pre-bonding, a small pressing force is applied to press the second integrated circuit die 100B against the first integrated circuit die 100A. The pre-bonding is performed at a low temperature, such as about room temperature, and after the pre-bonding, the dielectric layer 158 of the second integrated circuit die 100B is bonded to the dielectric layer 158 of the first integrated circuit die 100A. The bonding strength is then improved in a subsequent annealing step, in which the dielectric layer 158 of the first integrated circuit die 100A, the die connectors 164 of the first integrated circuit die 100A, the dielectric layer 158 the second integrated circuit die 100B, and the die connectors 164 of the second integrated circuit die 100B are annealed. After the annealing, direct bonds such as fusion bonds are formed, bonding the dielectric layer 158 of the first integrated circuit die 100A to the dielectric layer 158 of the second integrated circuit die 100B. For example, the bonds can be covalent bonds between the material of the dielectric layer 158 of the first integrated circuit die 100A and the material of the dielectric layer 158 of the second integrated circuit die 100B. The die connectors 164 of the first integrated circuit die 100A may be connected to the die connectors 164 of the second integrated circuit die 100B with a one-to-one correspondence. The die connectors 164 of the first integrated circuit die 100A and the die connectors 164 of the second integrated circuit die 100B may be in physical contact after the pre-bonding, or may expand to be brought into physical contact during the annealing. Further, during the annealing, the material of the die connectors 164 of the first integrated circuit die 100A and the die connectors 164 of the second integrated circuit die 100B (e.g., copper) intermingles, so that metal-to-metal bonds are also formed. Hence, the resulting bonds include both dielectric-to-dielectric bonds and metal-to-metal bonds.

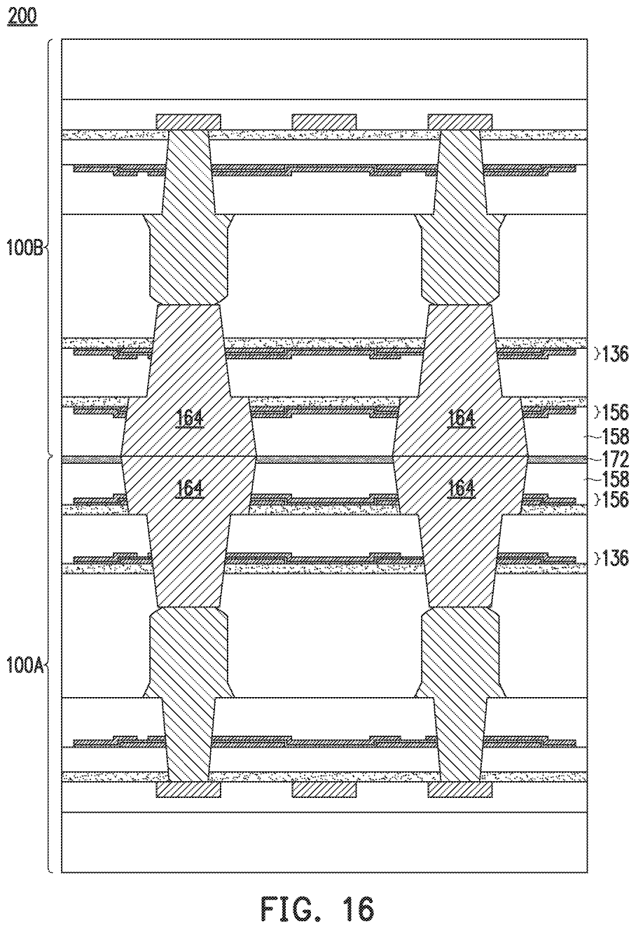

FIG. 16 is a cross-sectional view of a die structure 200, in accordance with some embodiments. This embodiment is similar to the embodiment of FIG. 15, except an anti-reflection layer 172 is formed between the dielectric layer 158 of the first integrated circuit die 100A and the dielectric layer 158 of the second integrated circuit die 100B. The anti-reflection layer 172 may be formed of a nitride such a silicon nitride, a metal oxide such as titanium oxide, or the like.

Embodiments may achieve advantages. As previously noted, the passivation layer 132 may be thick and flat, which may provide a large space on which passive devices 136 may be formed in subsequent processing. In this way, more passive devices may be embedded in an integrated circuit die 100, allowing for a greater degree of device integration. As a result, fewer passive devices may need to be externally attached to an integrated circuit die 100.

In an embodiment, a device includes: a plurality of redistribution lines over a semiconductor substrate, the redistribution lines including trace portions extending along the semiconductor substrate; a first passivation layer over the redistribution lines, the first passivation layer filling an entirety of an area between the trace portions of the redistribution lines; a passive device over the first passivation layer; a dielectric layer over the passive device; and a die connector extending through the dielectric layer, the die connector physically and electrically coupled to the passive device. In some embodiments of the device, the first passivation layer has a planar top surface that extends continuously over the redistribution lines and the area between the redistribution lines. In some embodiments, the device further includes: a second passivation layer between the first passivation layer and the semiconductor substrate, the planar top surface of the first passivation layer having a higher degree of planarity than a top surface of the second passivation layer. In some embodiments of the device, the passive device is a plate capacitor, the plate capacitor including a lower metal plate, an insulating layer on the lower metal plate, and an upper metal plate on the insulating layer. In some embodiments of the device, the passive device is a deep-trench capacitor, the deep-trench capacitor including an outer metal via, an insulating layer on the outer metal via, and an inner metal via on the insulating layer. In some embodiments of the device, the passive device is a resistor, the resistor including an insulating layer and a metal wire on the insulating layer. In some embodiments of the device, the passive device is an inductor, the inductor including a metal coil and an insulating layer on the metal coil.

In an embodiment, a device includes: a redistribution line over a semiconductor substrate, the redistribution line extending along the semiconductor substrate; a passivation layer over the redistribution line; a deep-trench capacitor including: an outer metal via extending into the passivation layer, the outer metal via extending beneath a top surface of the redistribution line; an inner metal via over the outer metal via; and an insulating layer between the inner metal via and the outer metal via; a first dielectric layer over the deep-trench capacitor; and a die connector extending through the first dielectric layer, the die connector physically and electrically coupled to the deep-trench capacitor. In some embodiments of the device, a dielectric material of the first dielectric layer is different than a dielectric material of the passivation layer. In some embodiments, the device further includes: a passive device over the first dielectric layer; and a second dielectric layer over the passive device. In some embodiments of the device, the die connector includes: a bond pad in the second dielectric layer; and a via in the first dielectric layer and in a portion of the passivation layer over the redistribution line. In some embodiments of the device, the portion of the passivation layer over the redistribution line has a thickness in a range of 2 kÅ to 10 kÅ. In some embodiments of the device, the deep-trench capacitor is a single-trench capacitor. In some embodiments of the device, the deep-trench capacitor is a multi-trench capacitor.

In an embodiment, a method includes: depositing a passivation layer over a redistribution line, the redistribution line extending along a semiconductor substrate; planarizing the passivation layer, a portion of the passivation layer remaining over the redistribution line after the passivation layer is planarized; forming a passive device over the passivation layer; depositing a dielectric layer over the passive device and the passivation layer; and forming a die connector through the dielectric layer and the portion of the passivation layer, the die connector physically and electrically coupled to the passive device and to the redistribution line. In some embodiments of the method, the portion of the passivation layer remaining over the redistribution line has a thickness in a range of 2 kÅ to 10 kÅ. In some embodiments of the method, forming the passive device includes: forming a first metal layer over the passivation layer, a first pattern of the first metal layer defining a first metal plate; depositing an insulating layer over the first metal layer; and forming a second metal layer over the insulating layer, a second pattern of the second metal layer defining a second metal plate. In some embodiments of the method, forming the passive device includes: forming recess in the passivation layer; forming a first metal layer in the recess, a first pattern of the first metal layer defining a first metal via; depositing an insulating layer over the first metal layer; and forming a second metal layer over the insulating layer, a second pattern of the second metal layer defining a second metal via. In some embodiments of the method, forming the passive device includes: forming a first metal layer over the passivation layer, the first metal layer being unpatterned; depositing an insulating layer over the first metal layer; and forming a second metal layer over the insulating layer, a pattern of the second metal layer defining a metal wire. In some embodiments of the method, forming the passive device includes: forming metal layer over the passivation layer, a pattern of the metal layer defining a metal coil; and depositing an insulating layer over the metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a plurality of redistribution lines over a semiconductor substrate, the redistribution lines comprising trace portions extending along the semiconductor substrate;
a first passivation layer over the redistribution lines, the first passivation layer filling an entirety of an area between the trace portions of the redistribution lines;
a passive device over the first passivation layer;
a dielectric layer over the passive device; and
a die connector extending through the dielectric layer, the die connector physically and electrically coupled to the passive device.

2. The device of claim 1, wherein the first passivation layer has a planar top surface that extends continuously over the redistribution lines and the area between the redistribution lines.

3. The device of claim 2, further comprising:
a second passivation layer between the first passivation layer and the semiconductor substrate, the planar top surface of the first passivation layer having a higher degree of planarity than a top surface of the second passivation layer.

4. The device of claim 1, wherein the passive device is a plate capacitor, the plate capacitor comprising a lower metal plate, an insulating layer on the lower metal plate, and an upper metal plate on the insulating layer.

5. The device of claim 1, wherein the passive device is a deep-trench capacitor, the deep-trench capacitor comprising an outer metal via, an insulating layer on the outer metal via, and an inner metal via on the insulating layer.

6. The device of claim 1, wherein the passive device is a resistor, the resistor comprising an insulating layer and a metal wire on the insulating layer.

7. The device of claim 1, wherein the passive device is an inductor, the inductor comprising a metal coil and an insulating layer on the metal coil.

8. A device comprising:
a redistribution line over a semiconductor substrate, the redistribution line extending along the semiconductor substrate;
a passivation layer over the redistribution line;
a deep-trench capacitor comprising:
an outer metal via extending into the passivation layer, the outer metal via extending beneath a top surface of the redistribution line;
an inner metal via over the outer metal via; and
an insulating layer between the inner metal via and the outer metal via;
a first dielectric layer over the deep-trench capacitor; and
a die connector extending through the first dielectric layer, the die connector physically and electrically coupled to the deep-trench capacitor.

9. The device of claim 8, wherein a dielectric material of the first dielectric layer is different than a dielectric material of the passivation layer.

10. The device of claim 8, further comprising:
a passive device over the first dielectric layer; and
a second dielectric layer over the passive device.

11. The device of claim 10, wherein the die connector comprises:
a bond pad in the second dielectric layer; and
a via in the first dielectric layer and in a portion of the passivation layer over the redistribution line.

12. The device of claim 11, wherein the portion of the passivation layer over the redistribution line has a thickness in a range of 2 kÅ to 10 kÅ.

13. The device of claim 8, wherein the deep-trench capacitor is a single-trench capacitor.

14. The device of claim 8, wherein the deep-trench capacitor is a multi-trench capacitor.

15. A method comprising:
depositing a passivation layer over a redistribution line, the redistribution line extending along a semiconductor substrate;
planarizing the passivation layer, a portion of the passivation layer remaining over the redistribution line after the passivation layer is planarized;
forming a passive device over the passivation layer;
depositing a dielectric layer over the passive device and the passivation layer; and
forming a die connector through the dielectric layer and the portion of the passivation layer, the die connector physically and electrically coupled to the passive device and to the redistribution line.

16. The method of claim 15, wherein the portion of the passivation layer remaining over the redistribution line has a thickness in a range of 2 kÅ to 10 kÅ.

17. The method of claim 15, wherein forming the passive device comprises:
forming a first metal layer over the passivation layer, a first pattern of the first metal layer defining a first metal plate;
depositing an insulating layer over the first metal layer; and
forming a second metal layer over the insulating layer, a second pattern of the second metal layer defining a second metal plate.

18. The method of claim 15, wherein forming the passive device comprises:
forming recess in the passivation layer;
forming a first metal layer in the recess, a first pattern of the first metal layer defining a first metal via;
depositing an insulating layer over the first metal layer; and
forming a second metal layer over the insulating layer, a second pattern of the second metal layer defining a second metal via.

19. The method of claim 15, wherein forming the passive device comprises:
forming a first metal layer over the passivation layer, the first metal layer being unpatterned;
depositing an insulating layer over the first metal layer; and
forming a second metal layer over the insulating layer, a pattern of the second metal layer defining a metal wire.

20. The method of claim 15, wherein forming the passive device comprises:
forming metal layer over the passivation layer, a pattern of the metal layer defining a metal coil; and
depositing an insulating layer over the metal layer.
